(19) United States
(12) Patent Application Publication
(10) Pub. No.: US 2015/0255930 A1
(43) Pub. Date: Sep. 10, 2015

(54) INTERFACES WITH BUILT-IN TRANSIENT VOLTAGE SUPPRESSION

(71) Applicant: Gilbert Lee, Saratoga, CA (US)

(72) Inventor: Gilbert Lee, Saratoga, CA (US)

(21) Appl. No.: 14/197,202

(22) Filed: Mar. 4, 2014

(51) Int. Cl. H01R 13/66; H02H 3/22; H05K 9/00

(52) U.S. Cl. CPC H01R 13/665; H05K 9/0067; H05K 9/0009; H02H 3/22

(57) ABSTRACT

An interface for protecting electronic devices from external Electric Over-Stress (EOS), Electromagnetic Interference (EMI) and Electrostatic Discharge (ESD) is disclosed. The interface is coupled to a PCB having electronic circuits. The interface device comprises a plurality of conducting lines for establishing electrical communication with the circuits on the PCB, wherein each conducting line has a distinct potential; and protection components connected to the conducting lines in the interface to shunt the EOS/EMI/ESD energy therethrough in the event of EOS occurring on the conducting lines.

### FIELD OF DISCLOSURE

The present disclosure relates to prevention of Electrical Over-Stress (EOS), Electromagnetic Interference (EMI) and Electrostatic Discharge (ESD) in interface devices or connectors.

### DEFINITIONS

The expression “Electric Over-Stress (EOS), Electromagnetic Interference (EMI) and Electrostatic Discharge (ESD)” used in the context of this disclosure refers to a condition wherein an electronic device and/or circuit is subjected to voltage and/or current that exceeds normal operating parameters. This definition is in addition to those used in the art.

### BACKGROUND

Electronic devices have various causes of failure such as excess temperature, excess current and/or voltage, mechanical shock, stress or impact, and the like. Electronic devices and circuits are exposed to transient voltages or currents generated during occurrence of several harmful conditions such as Electrical Over-Stress (EOS), Electromagnetic Interference (EMI), Electrostatic Discharge (ESD), surges and spikes during electrical communication. Generally, electronic devices have limited protection and EOS/EMI/ESD handling capacity, thereby making the devices susceptible to damage during occurrence of these harmful conditions. In an event of occurrence of any of these harmful conditions, there is a high rise in current and/or voltage at the input terminals of the electronic devices. This abrupt change in current and/or voltage at the input terminals can lead to failure of electronic devices.

An electronic device typically includes at least one circuit designed to meet the functional requirements of the electronic device. Conventionally, the process of making an electronic device begins with a technical specification that specifies electrical requirements such as the input/output signals, power requirements and the like, to achieve the functional requirements of the electronic device. The specification also includes physical parameters that the electronic device must meet, such as size, weight, moisture resistance, temperature range, thermal output, vibration tolerance and the like. Based on the specification, a circuit is designed wherein individual circuit components are chosen to carry out each function in the circuit and the interconnection of the components to achieve the overall functionality is decided and schematically represented. Thereafter, the physical layout typically in the form of Printed Circuit Board (PCB) layout of designed circuit is created and the PCB is fabricated.

The circuit components chosen typically include operational components that carry out each function in the circuit and protection components that are used around the operational components to protect the circuit from the aforementioned harmful conditions of EOS/EMI/ESD. The operational components typically include active components such as semiconductors, transistors, diodes and the like, and passive components such as resistors, capacitors and the like. The protection components typically include Transient Voltage Suppression (TVS) diodes, zener diode, Schottky diode, varactor diode, clamper, and the like. Additionally, semiconductor packages having a plurality of such diodes are also used.

The PCB has to accommodate both the operational as well as protection components. However an electronic device having size constraints puts restriction on the size of PCB whereby the PCB area for circuit components is reduced. This leads to thinner electrical conducting channels and inappropriately placed circuit components, resulting in increase in parasitic impedances. This makes the routing of conducting channels difficult and the design and layout of the circuit extremely time consuming. In an EOS event, the parasitic impedances cause improper functioning of the operational components as well as the protection components on the PCB, thereby causing failure of the electronic device.

Additionally, the requirement of protection components is also related to the number of conducting channels. Hence the number of protection components required on the PCB increases as the number of conducting channels increases, thus necessitating the use of larger PCB's. The increased number of protection components on the PCB and the necessity of larger PCB for the protection components results in increased cost of fabrication of the PCB leading to an increase in the overall cost of the electronic device.

Hence there is a need to alleviate the drawbacks associated with use of protection components for protecting electronic devices and circuits.

### Objects

Some of the objects of the present disclosure aimed to ameliorate one or more problems of the prior art or to at least provide a useful alternative are listed herein below.

An object of the present disclosure is to provide much enhanced protection performance against the harmful conditions of EOS/EMI/ESD.

An object of the present disclosure is to provide an interface that facilitates the use of a compact PCB therewith.

Another object of the present disclosure is to provide an interface that is cost effective.

Another object of the present disclosure is to provide an interface that facilitates reduction in maintenance costs of electronic devices.

Other objects and advantages of the present disclosure will be more apparent from the following description when read in conjunction with the accompanying figures, which are not intended to limit the scope of the present disclosure.

### SUMMARY

In accordance with the present disclosure, there is provided an interface comprising at least a portion of an EOS/EMI/ESD protection arrangement, the interface adapted to be detachably coupled to an electronic device for protection thereof.

Typically, the interface includes at least one first connector adapted to engage with a second connector associated with the electronic device.

Generally, the connector is a male/female type connector.

Generally, the interface is selected from the group consisting of Universal Serial Bus (USB) interface, High Definition Multimedia Interface (HDMI) interface, Displayport (DP) interface, IEEE1394 interface, Video Graphic Array (VGA) interface and Digital Visual Interface (DVI) interface, and the like.

Typically, the USB interface is selected from the group consisting of Micro USB interface, Mini USB interface and Standard USB interface;

Typically, the EOS/EMI/ESD protection arrangement comprises at least one component selected from the group consisting of Transient Voltage Suppression (TVS) diode, zener diode, varactor diode, avalanche diode and clamper.

Additionally, the EOS/EMI/ESD protection arrangement comprises at least a portion of components selected from the group consisting of Transient Voltage Suppression (TVS) diode, zener diode, varactor diode, avalanche diode and clamper.

Typically, the interface includes a plurality of conducting channels and the EOS/EMI/ESD protection arrangement is electrically coupled to at least two conducting channels.

### BRIEF DESCRIPTION OF ACCOMPANYING DRAWINGS

The interface of the present disclosure will now be described with the help of the accompanying drawings, in which:

FIG. 1 illustrates an arrangement of a conventional interface co-operating with a PCB having protection components mounted thereon;

FIG. 2 illustrates the occurrence of an EOS/EMI/ESD event in a line/channel on the PCB of FIG. 1;

FIG. 3 illustrates a graphical representation depicting hazardous effects of parasitic impedances on the operation of protection components on the PCB of FIG. 1;

FIG. 4 illustrates an interface having an EOS/EMI/ESD protection arrangement therein, in accordance with an embodiment of the present disclosure;

FIG. 5 illustrates the interface of FIG. 4 co-operating with a PCB;

FIG. 6 illustrates the occurrence of an EOS/EMI/ESD event in a line/channel in the EOS/EMI/ESD protection arrangement of FIG. 4; and

FIG. 7 illustrates a graphical representation depicting the current and voltage during an EOS/EMI/ESD event and the clamping achieved by the interface of FIG. 4 during the EOS/EMI/ESD event.

### DETAILED DESCRIPTION

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

The use of the expression “at least” or “at least one” suggests the use of one or more elements or ingredients or quantities, as the use may be in the embodiment of the invention to achieve one or more of the desired objects or results.

Interfaces are used to achieve electrical communication between a plurality of electronic devices and circuits. Interfaces typically include connectors co-operating with a Printed Circuit Board (PCB) having circuits mounted thereon. The interfaces are generally classified as ‘male’ and ‘female’ interfaces that are connected together to achieve electrical communication between the electronic devices. During the course of electrical communication, electronic devices are exposed to transient voltages or currents generated during occurrence of several harmful conditions such as Electrical Over-Stress (EOS), Electromagnetic Interference (EMI), Electrostatic Discharge (ESD), surges and spikes. EOS/EMI/ESD typically occurs when excessive voltage or current is applied to the terminals of an electronic device. EOS/EMI/ESD can occur due to various factors such as, incorrectly connected the interfaces while the PCB is powered up causing a short between two or more pins in the interfaces, incorrect power source or orientation and the like, resulting in a surge in the voltage/current. The excessive voltage applied to the terminals may result in the failure of the electronic device. In order to protect electronic devices from these harmful conditions, protection devices such as Transient Voltage Suppression (TVS) diodes, zener diode, varactor diode, clamper, and the like are used in the electronic circuit of these devices to dissipate the EOS/EMI/ESD energy due to the excessive transient voltage/current. Additionally, semiconductor packages having a plurality of such diodes are also used.

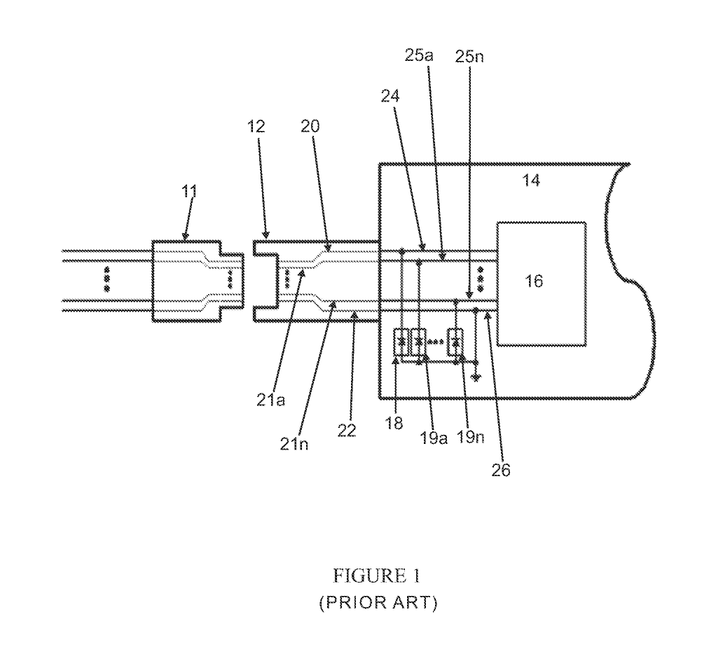

Referring to FIG. 1, an arrangement of a conventional interface co-operating with a PCB having protection components mounted thereon is illustrated. In accordance with an exemplary embodiment of FIG. 1, the conventional interface includes a first interface which is a male interface (11) and a second interface which is a female interface (12) that is co-operating with a PCB (14). The male interface (11) may be co-operating with another PCB directly or through a connected cable. Alternately, the male interface (11) may be included in data cable.

The female interface (12) typically includes a plurality of electrical conducting lines/channels that are connected to corresponding conducting lines/channels in the PCB (14) when the female interface (12) co-operates with the PCB (14). The conducting channels are further connected to operational components of a circuit (16) on the PCB (14). Similarly, the male interface (11) typically includes a plurality of conducting lines/channels that are connected to corresponding conducting lines/channels in the PCB co-operating with the male interface (11). Furthermore, the conducting lines of the female interface (12) engage with corresponding conducting lines of the male interface (11) when the interface devices (11, 12) are connected together to establish electrical communication between the circuitry on the separate PCB's. The conducting lines in the interfaces typically include data, power and ground lines.

In accordance with the exemplary embodiment of FIG. 1, the interface (12) includes a first conducting line (20) and a second conducting line (22), wherein, the first conducting line (20) is connected to a corresponding first conducting channel (24) and the second conducting line (22) is connected to a corresponding second conducting channel (26) on the PCB (14) when the interface (12) co-operates with the PCB (14). The interface (12) includes additional conducting lines (21a-21n) and the PCB includes corresponding conducting channels (25a-25n). The conducting channels (24, 25a-25n and 26) enable data and power transfer to the operational components of the circuit (16) on the PCB (14).

In accordance with the exemplary embodiment of FIG. 1, the first conducting channel (24) is at a higher potential than the second conducting channel (26), wherein the first conducting channel (24) is a power supply channel and the second conducting channel (26) is a ground channel. Typically, each conducting channel has a distinct potential. A protection component (18) is used between the first conducting channel/power supply channel (24) and the second conducting channel/ground channel (26) of the PCB (14). Similarly protection components (19a-19n) are used between the conducting channels (25a-25n) and the second conducting channel (26) respectively. The protection components (18, 19a-19n) are decoupled between their own lines and the ground channel (26). Furthermore, more complex protection components/devices may be required based on the EOS/EMI/ESD specification of each electronic device. Moreover EOS/EMI/ESD protection specification of each conducting channel of a PCB may be different, whereby each channel may require its own unique protection component.

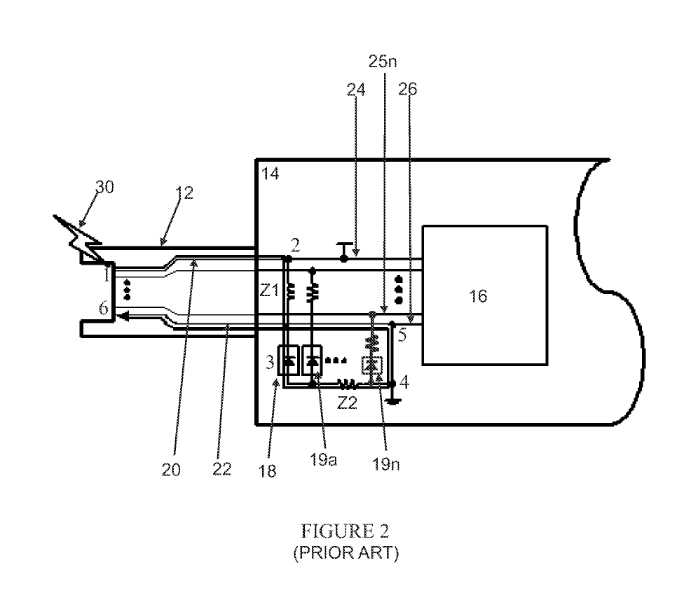

Referring to FIG. 2, the occurrence of an EOS/EMI/ESD event in a line/channel on the PCB of FIG. 1 is illustrated. During the EOS/EMI/ESD event, destructive EOS/EMI/ESD energy (30) intrudes into the PCB via the interface (12). As a result substantial transient voltage is applied at a node 1 on the first conducting line (20). This causes the current (Ip) flowing across the first conducting line to abruptly increase. This transient spike in the current further flows into the first conducting channel (24) connected to the first conducting line, thereby leading to destructive induced voltage, unendurable current density, excessive heating of the operational components of the circuit (16) connected to the first conducting channel (24). This spike in the current may cause thermal damage of the electronic devices.

The protection component (18) coupled between the first conducting channel (24) and the second conducting channel (26) shunts the excessive current on the first conducting channel (24) to ground by providing a path through itself to the second conducting channel (26). The path defined by nodes 1-2-3-4-5-6 depicts the flow of current during the EOS/EMI/ESD event.

However, the arrangement described in FIGS. 1 and 2, suffers from several drawbacks. A major drawback associated with the arrangement is the development of parasitic impedances (Z1, Z2) on conducting channels on the PCB (14) resulting in weak performance of the protection components. The determination of parasitic impedances (Z1, Z2) depends on the length, width, thickness and material of the conducting channels (24, 26) on the PCB (14). The impedance Z1 is developed across the path defined by nodes 2-3, and the impedance Z2 is developed across the path defined by nodes 3-4-5. Generally, the parasitic impedance of metal channels is modeled by resistance, inductance and capacitance but the resistance and inductance have a significant effect on the operation of the protection components (18, 19a-19n).

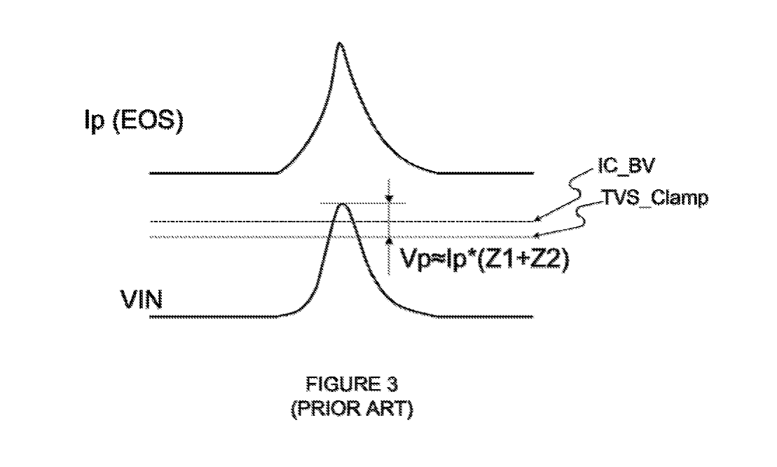

Referring to FIG. 3, a graphical representation depicting hazardous effects of parasitic impedances on the operation of protection components on the PCB of FIG. 1 is illustrated. FIG. 3 illustrates a current waveform and a voltage waveform representing an increase in the value of current and voltage during the EOS/EMI/ESD event. When the destructive EOS/EMI/ESD energy intrudes the first conducting channel (24) during the EOS/EMI/ESD event, the parasitic impedances (Z1, Z2) cause an unnecessary voltage drop in the current shunt path defined by nodes 1-2-3-4-5-6 leading to an increase in the clamping voltage (TVS_Clamp) of the protection device (18). The voltage of first conducting channel (24) is denoted by VIN and the current flowing through the circuit during the EOS/EMI/ESD event is denoted by Ip. Generally, the protection component (18) protects the operational components of the circuit (16) by maintaining the voltage level (TVS_Clamp) lower than a breakdown voltage level (IC_BV) of the operational components of the circuit (16). The protection component (18) blocks voltages of magnitude greater than their clamping voltage level (TVS_Clamp) and must have lower clamping voltage than a breakdown voltage of the operational components.

However, the parasitic impedances (Z1, Z2) cause the clamping voltage (TVS_Clamp) to overshoot. The rise in voltage level (Vₚ) is calculated in the following manner, Vₚ≈Iₚ*(Z1+Z2)

Ideally, the overshooting VIN must be limited to the clamping voltage (TVS_Clamp) by the protection component (18) under normal operating conditions. However, the effect of increased parasitic impedances (Z1, Z2) causes the voltage VIN to increase beyond the breakdown voltage (IC_BV) of the electronic devices, thereby resulting in irrecoverable failure of the operational components of the circuit (16).

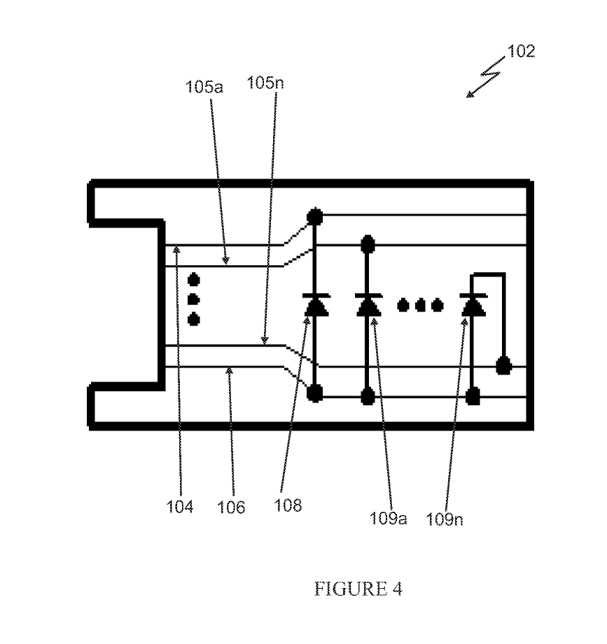

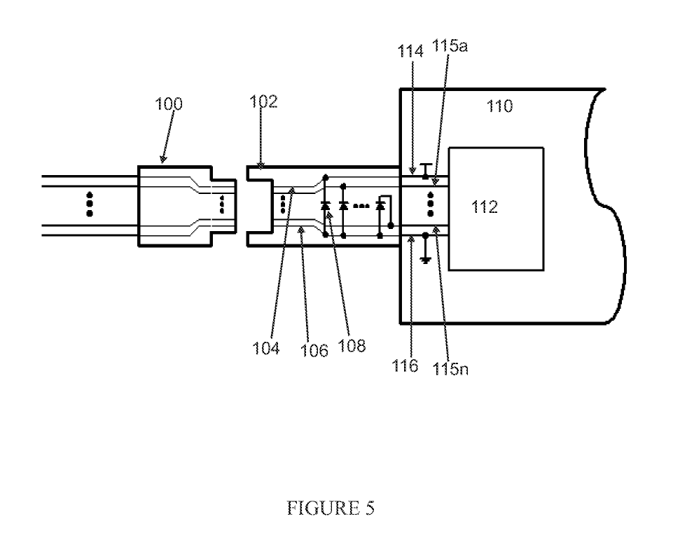

Referring to FIGS. 4 and 5, an interface having an EOS/EMI/ESD protection arrangement therein, in accordance with an embodiment of the present disclosure and the interface co-operating with a PCB, respectively is illustrated. In accordance with an exemplary embodiment of FIGS. 4 and 5, the interface includes a first interface (100) which is a male interface and a corresponding second interface (102) which is a female interface. However, the mating configuration of interfaces (100, 102) is not limited to the configuration as described herein, as the interfaces (100, 102) respectively may be connected in interchangeable mating configuration. The female interface (102) is further coupled to a PCB (110). The male interface (100) may be coupled to another PCB directly or through a connected cable. Alternately the male interface (100) may be included in data cable. The interfaces (100, 102) are coupled to their respective PCB's typically by soldering. The interfaces (100, 102) include, but are not limited to, Universal Serial Bus (USB) interface, High Definition Multimedia Interface (HDMI) interface, Displayport (DP) interface, IEEE1394 interface, Video Graphic Array (VGA) interface and Digital Visual Interface (DVI) interface. Furthermore, the USB interface includes Micro USB interface, Mini USB interface and Standard USB interface; and the DP interface includes all interfaces specified by the Video Electronics Standards Association (VESA). The interfaces (100, 102) are typically connectors.

The female interface (102) typically includes a plurality of conducting lines/channels that are connected to corresponding conducting lines/channels in the PCB (110) when the female interface (102) is coupled to the PCB (110). The conducting channels are further connected to operational components of a circuit (112) on the PCB (110). Similarly, the male interface device (100) typically includes a plurality of conducting lines/channels that are connected to corresponding conducting lines/channels in the PCB coupled to the male interface device (100). Furthermore, the conducting lines of the female interface (102) engage with corresponding conducting lines of the male interface (100) when the interfaces (100, 102) are connected together to establish electrical communication between the circuitry on the separate PCB's. The conducting lines in the interfaces typically include data, power and ground lines.

In accordance with the exemplary embodiment of FIGS. 4 and 5, the interface (102) of the present disclosure includes a first conducting line (104) and a second conducting line (106) and additional conducting lines (105a-105n). The first conducting line (104) is connected to corresponding first conducting channel (114) and the second conducting line (106) is connected to a corresponding second conducting channel (116) on the PCB (110) when the interface (102) is coupled to the PCB (110). The PCB includes corresponding additional conducting channels (115a-115n). The conducting channels (114, 115a-115n and 116) enable data and power transfer to operational components of the circuit (112) on the PCB (110).

Further, the interface (102) of the present disclosure includes an EOS/EMI/ESD protection arrangement wherein a protection component (108), typically a Transient Voltage Suppression (TVS) device, is coupled between the first conducting line (104) and the second conducting line (106). Similarly, the protection components (109a-109n) are coupled between additional conducting lines (105a-105n) and the second conducting line (106) respectively. The protection components (108, 109a-109n) include but are not limited to TVS diode, zener diode, schottky diode, varactor diode, an avalanche diode and clamper. The EOS/EMI/ESD protection arrangement comprising the protection components (108, 109a-109n) are built-in the interface (102), thereby eliminating the need of mounting the protection components on the PCB as required in the prior art.

In accordance with the exemplary embodiment of FIGS. 4 and 5, the first conducting line (104) is at a higher potential than that of the second conducting line (106), wherein the first conducting line (104) is a power supply line and the second conducting line (106) is a ground line. Thus, the protection component (108) is electrically coupled between the first conducting line/power supply line (104) and the second conducting line/ground line (106). Typically, each conducting line has a distinct potential.

During the occurrence of EOS/EMI/ESD, when the potential across the first conducting line (104) and the second conducting line (106) exceeds a pre-determined value, the protection component (108) provides a low impedance path for the transient current, thereby protecting the operational components of the circuit (112) on the PCB (110). The connection of the protection component (108) in the interface (102) enables the use of compact and smaller sized PCB (110) as compared to PCB (14) of the prior art, thereby facilitating easy and efficient routing of the operational components of the circuit (112) on the PCB (110).

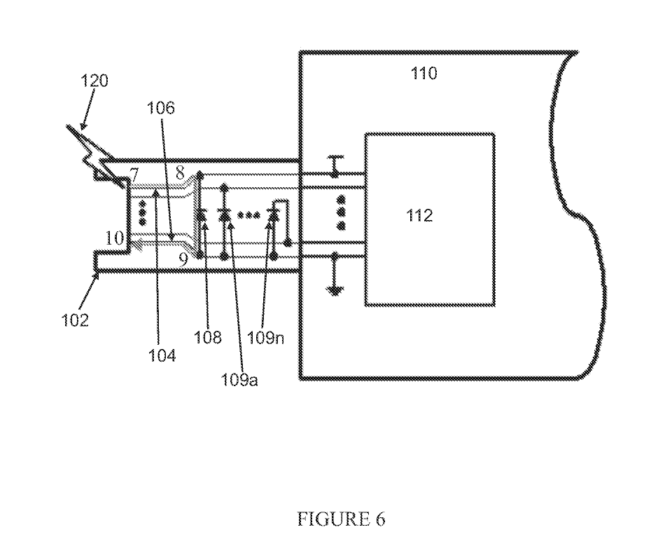

Referring to FIG. 6, the occurrence of an EOS/EMI/ESD event in a line/channel in the EOS/EMI/ESD protection arrangement of FIG. 4 is illustrated. The transient voltage (120) present at the node 7 on the first conducting line (104), during the EOS/EMI/ESD event, causes the current (Ip) flowing across the first conducting line (104) to abruptly increase. The protection component (108) coupled between the first conducting line (104) and the second conducting line (106) shunts the excessive current from the first conducting line (104) to ground by providing a path through itself to the second conducting line (106), without allowing the excessive current to pass through to the PCB (110). The path defined by nodes 7-8-9-10 represents the flow of current through the protection component (108), during the EOS/EMI/ESD event. The excessive current flowing through the first conducting line (104) is diverted back from the interface (102) itself via the protection component (108), thereby preventing the flow of excessive current towards the PCB (110). Further, there is minimal effect of parasitic impedances on the protection component (108) during the conduction of excessive current during the EOS/EMI/ESD event. The parasitic impedances associated with conducting channels of the PCB (110), if any, do not intervene with the functioning of the protection component (108).

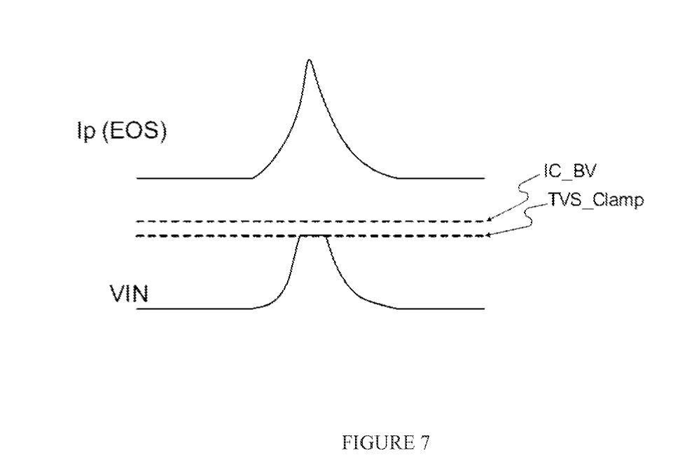

Referring to FIG. 7, a graphical representation depicting the current and voltage during an EOS/EMI/ESD event and the clamping achieved by the interface of FIG. 6 during the EOS/EMI/ESD event is illustrated. Iₚ represents the surge current developed during the EOS/EMI/ESD event. The clamping voltage (TVS_Clamp) is lesser than the breakdown voltage (IC_BV) of the operational components of the circuit (112). The protection components (108, 109a-109n) are selected as per the system requirements i.e. current and voltage specifications of the operational components of the circuit (112). Due to minimization of parasitic impedances, there is no overshoot of voltage and therefore the voltage across the operational components of the circuit (112) is limited to the clamping voltage of the protection component (108).

Thus the interface of the present disclosure having the protection components therein, when coupled to a PCB, enables efficient protection of components mounted on a PCB by diverting the excessive voltage/current from the interface itself via the protection component and preventing the flow of excessive current towards the PCB. Furthermore, the location of the protection components in interface facilitates reduction in PCB size resulting in reduced cost of development of the PCB and further reduction in overall cost of electronic devices. Moreover in case of any breakdown in any protection component due to EOS/EMI/ESD, only the interface needs to be replaced thereby maintaining the same PCB, leading to reduction in maintenance costs of the electronic devices.

### Technical Advantages and Economic Significance

The technical advancements offered by the interface of the present disclosure include the realization of:
providing much enhanced protection performance against the harmful conditions of EOS/EMI/ESD;
facilitating use of protection components within the interface device;
providing protection to electronic devices from harmful effects of EOS/EMI/ESD;
facilitating the use of a compact PCB; and
providing an economical interface.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

1. An interface comprising at least a portion of an EOS/EMI/ESD protection arrangement, said interface adapted to be detachably coupled to an electronic device for protection thereof.

2. The interface as claimed in claim 1, wherein said interface includes at least one first connector adapted to engage with a second connector associated with the electronic device.

3. The interface as claimed in claim 2, wherein said connector is a male/female type connector.

4. The interface as claimed in claim 1, wherein said interface is selected from the group consisting of Universal Serial Bus (USB) interface, High Definition Multimedia Interface (HDMI) interface, Displayport (DP) interface, IEEE1394 interface, Video Graphic Array (VGA) interface and Digital Visual Interface (DVI) interface, and all kinds of connectors for data interfacing, battery charging, OTG (On-the-Go) function, docking application in the mobile phones or hand-held electric equipments.

5. The interface as claimed in claim 4, wherein said USB interface is selected from the group consisting of Micro USB interface, Mini USB interface and Standard USB interface; and said DP interface includes all interfaces specified by the Video Electronics Standards Association (VESA).

6. The interface as claimed in claim 1, wherein said EOS/EMI/ESD protection arrangement comprises at least one component selected from the group consisting of Transient Voltage Suppression (TVS) diode, zener diode, varactor diode, avalanche diode and clamper.

7. The interface as claimed in claim 1, wherein said EOS/EMI/ESD protection arrangement comprises at least a portion of components selected from the group consisting of Transient Voltage Suppression (TVS) diode, zener diode, varactor diode, avalanche diode and clamper.

8. The interface as claimed in claim 1, wherein said interface includes a plurality of conducting channels and said EOS/EMI/ESD protection arrangement is electrically coupled to at least two conducting channels.
